(19) United States
(12) Patent Application Publication
(10) Pub. No.: US 2009/0061578 A1
(43) Pub. Date: Mar. 5, 2009

(54) Method of Manufacturing a Semiconductor Microstructure

(76) Inventors: Siew-Seong Tan, Hsinchu City (TW); Chen-Yen Liu, Hsinchu City (TW)

Correspondence Address: Dr. BANGER SHIA, 102 Lindencrest Ct., Sugar Land, TX, 77479-5201, US

(21) Appl. No.: 11/847,579

(22) Filed: Aug. 30, 2007

(51) Int. Cl. H01L 21/8238

(52) U.S. Cl. 438/200; 257/E21.632

(57) ABSTRACT

A method of manufacturing a semiconductor microstructure comprises: forming a standard CMOS wafer with at least one micro-electro-mechanical structure on a top surface of a silicon substrate, forming at least one sacrificial layer and one resist layer sequentially on the top surface of the CMOS wafer; forming an etching resist layer on a lower rear surface of the silicon substrate, etching the lower rear surface of the silicon base by deep reactive ion etching or wet etching to form a space corresponding to the micro-electro-mechanical structure, and etching the CMOS wafer and the sacrificial layer, respectively, to cause suspension of the micro-electro-mechanical structure. Such arrangements effectively prevent the occurrence of undercut, reduce the exposure and possibility of damage of the micro-electro-mechanical structure, and effectively save the package cost.

### BACKGROUND OF THE INVENTION

1. Field of the Invention

The present invention relates to a method of manufacturing a semiconductor, and more particularly to a method of manufacturing a semiconductor microstructure, in addition to causing suspension of the micro-electro-mechanical structure, this method further effectively prevents the undercut, reduces the exposure and possibility of damage of the micro-electro-mechanical structure, and effectively saves the package cost.

2. Description of the Prior Art

The existing semiconductor micro-electro-mechanical system includes various micro-electro-mechanical structures, such as: unmovable probe, flow passage, cavity structure, or some other structures, like moveable springs, linkage, gears (rigid motion or flexible deformation), etc.

Various semiconductor applications can be formed by incorporating the above various structures into relative semiconductor micro-electro-mechanical circuits. Hence, how to improve the various functions of the micro mechanical structures with the manufacturing methods is the key point of the future semiconductor micro-electro-mechanical system and is also the toughest challenge in further researching the chip. The development potential will be inestimable if the manufacturing method is improved.

The existing method of manufacturing the micro-electro-mechanical sensing device and the starter usually needs to make a suspension structure on a silicon substrate, and the manufacturing process must adopt advanced semiconductor technology, such as the dry etching of high-aspect-ratio structure and sacrificial-layer in MEMS (micro-electro-mechanical systems).

The conventional technologies, such as the one disclosed in U.S. Pat. No. 6,458,615B1, are usually to form a standard CMOS (Complementary Metal-Oxide Semiconductor) wafer with at least one micro-electro-mechanical structure on the top surface of the silicon substrate, and then the etching is processed layer by layer from top surface. After the side edge of the micro-electro-mechanical structure is etched, isotropic etching is carried out to etch the silicon substrate, thus causing the suspension of the micro-electro-mechanical structure.

The above conventional method can manufacture the suspended micro-electro-mechanical structure, however, it also has the following disadvantages:

First, it adopts anisotropic dry chemical etching and uses chemical reaction to remove the isolation layer, however, after the side edge of the micro-electro-mechanical structure is etched, the silicon substrate still needs to be massively etched by isotropic chemical etching, and this technique will produce serious undercut problems.

Second, the micro-electro-mechanical structure is always exposed to the manufacturing process of this conventional technology, and after the long time of multi-layer processing, the micro-electro-mechanical structure is likely to be dirtied or damaged, leading to a low rate of good products.

Third, after etching process is finished, the micro-electro-mechanical structure can already be suspended, special means is required to airtightly package the surface of the micro-electro-mechanical structure. However, the micro-electro-mechanical structure must be ensured in a suspended state. The conventional method is to use a special cover to cover the surface of the product, and then precisely make a package film without touching the micro-electro-mechanical structure, and this package technology is complicated and high cost and is incompatible with the IC (integrated circuit) package technology.

To solve the disadvantages, U.S. Pat. No. 6,712,983 B2 discloses a Reactive Ion Etching technology which substantially reduces the occurrences of undercut. However, its etching is also carried out layer by layer from the top downward, the last one etching of the silicon substrate can only be performed by using horizontal etching technology. Hence, this improved conventional technology is still complicated and troublesome, and the micro-electro-mechanical structure still has the problem of undercut after massive etching and horizontal etching. Furthermore, the problems of the exposure of the micro-electro-mechanical structure and being not good for later packaging have still not been improved.

The present invention has arisen to mitigate and/or obviate the afore-described disadvantages.

### SUMMARY OF THE INVENTION

The primary objective of the present invention is to provide a method of manufacturing a semiconductor microstructure which effectively prevents the occurrence of undercut.

To achieve the above objective, a method of manufacturing a semiconductor microstructure provided by the present invention comprises: forming a standard CMOS wafer with at least one micro-electro-mechanical structure on a top surface of a silicon substrate, forming at least one sacrificial layer and one resist layer sequentially on the top surface of the CMOS wafer; forming an etching resist layer on a lower rear surface of the silicon substrate, etching the lower rear surface of the silicon base by deep reactive ion etching or wet etching to form a space corresponding to the micro-electro-mechanical structure, and etching the CMOS wafer and the sacrificial layer, respectively, to cause suspension of the micro-electro-mechanical structure.

Etching the lower rear surface of the silicon substrate by deep reactive ion etching can reduce the time of etching the micro-electro-mechanical structure and reduce the amount of undercut, and by cooperating with the technology of deep reactive ion etching and reactive ion etching, the micro-electro-mechanical structure can be effectively prevented from undercutting.

The secondary objective of the present invention is to provide a method of manufacturing a semiconductor microstructure which effectively prevents the undercut, reduces the exposure and possibility of damage of the micro-electro-mechanical structure, and effectively saves the package cost.

To achieve the above objective, a method of manufacturing a semiconductor microstructure provided by the present invention comprises: forming at least one sacrificial layer and one resist layer sequentially on the top surface of the CMOS wafer; etching the lower rear surface of the silicon base by deep reactive ion etching to form a space corresponding to the micro-electro-mechanical structure, and etching the CMOS wafer and the sacrificial layer, respectively, to cause suspension of the micro-electro-mechanical structure, and the top of the micro-electro-mechanical structure is still sealed with the resist layer.

With the unique technology of etching the lower rear surface of the silicon substrate by deep reactive ion etching, from the beginning of the etching process to the suspension, the top of the micro-electro-mechanical structure of the CMOS wafer is always protected with the resist layer, thus effective preventing the exposure of the micro-electro-mechanical structure and reducing the and possibility of damage thereof.

It is more important that since the resist layer on the top surface of the CMOS wafer can directly be used as a package structure for sealing the micro-electro-mechanical structure. Therefore, the present invention is saved from the complicated and high package process.

Another objective of the present invention is to provide a method of manufacturing a semiconductor microstructure which can freely control the thickness and weight of the micro-electro-mechanical structure or make the conductor resist layer, thus effectively increasing the patterns of the micro-electro-mechanical structure while reducing the cost.

To achieve this objective, since the sacrificial layer is the last layer to be etched, the present invention utilizes plural storing layers and the sacrificial layer to adjust the thickness and weight of the micro-electro-mechanical structure. Furthermore, the resist layer will become a hollow package. And the micro-electro-mechanical structure can be electrically connected if the conductor resist layer is adopted.

The conductor resist layer can be made of high conductivity metal, including aluminum, nickel, silver, copper, or gold and is directly electrically connected to the micro-electro-mechanical structure.

It is noted that deep reactive ion etching is an anisotropic etching technology which is recognized as a very important etching technology in recent years, which utilizes the protection layer formed during the etching process to prevent the undercut problem. Therefore, etched structure and shape is free of the influence of the lattice plane and don't have convex corner and undercut. Hence, it can be etched into various shaped holes or convex blocks. In addition, with the reactive ion etching lag, the surface of the substrate can be etched to have different heights.

However, the conventional dry deep etching technology don't have the effect of convex corner and undercut, therefore, it is difficult to make a suspended micro-electro-mechanical structure. The present invention can reduce the difficulties of manufacturing a suspended micro-electro-mechanical structure by using the special technology of reverted etching.

### BRIEF DESCRIPTION OF THE DRAWINGS

FIG. 1 shows a first step of a method of manufacturing a semiconductor microstructure in accordance with a first embodiment of the present invention;

FIG. 2 shows a second step of the method of manufacturing a semiconductor microstructure in accordance with the first embodiment of the present invention;

FIG. 3 shows a third step of the method of manufacturing a semiconductor microstructure in accordance with the first embodiment of the present invention;

FIG. 4 shows a fourth step of the method of manufacturing a semiconductor microstructure in accordance with the first embodiment of the present invention;

FIG. 5 shows a fifth step of the method of manufacturing a semiconductor microstructure in accordance with the first embodiment of the present invention;

FIG. 6 shows a first step of a method of manufacturing a semiconductor microstructure in accordance with a second embodiment of the present invention;

FIG. 7 shows a second step of the method of manufacturing a semiconductor microstructure in accordance with the second embodiment of the present invention;

FIG. 8 shows a third step of the method of manufacturing a semiconductor microstructure in accordance with the second embodiment of the present invention;

FIG. 9 shows a fourth step of the method of manufacturing a semiconductor microstructure in accordance with the second embodiment of the present invention;

FIG. 10 shows a fifth step of the method of manufacturing a semiconductor microstructure in accordance with the second embodiment of the present invention;

FIG. 11 shows a sixth step of the method of manufacturing a semiconductor microstructure in accordance with the second embodiment of the present invention;

FIG. 12 shows a seventh step of the method of manufacturing a semiconductor microstructure in accordance with the second embodiment of the present invention;

FIG. 13 shows a first step of a method of manufacturing a semiconductor microstructure in accordance with a third embodiment of the present invention;

FIG. 14 shows a second step of the method of manufacturing a semiconductor microstructure in accordance with the third embodiment of the present invention;

FIG. 15 shows a third step of the method of manufacturing a semiconductor microstructure in accordance with the third embodiment of the present invention;

FIG. 16 shows a fourth step of the method of manufacturing a semiconductor microstructure in accordance with the third embodiment of the present invention;

FIG. 17 shows a fifth step of the method of manufacturing a semiconductor microstructure in accordance with the third embodiment of the present invention;

FIG. 18 shows a sixth step of the method of manufacturing a semiconductor microstructure in accordance with the third embodiment of the present invention;

FIG. 19 shows a first step of a method of manufacturing a semiconductor microstructure in accordance with a fourth embodiment of the present invention;

FIG. 20 shows a second step of the method of manufacturing a semiconductor microstructure in accordance with the fourth embodiment of the present invention;

FIG. 21 shows a third step of the method of manufacturing a semiconductor microstructure in accordance with the fourth embodiment of the present invention;

FIG. 22 shows a fourth step of the method of manufacturing a semiconductor microstructure in accordance with the fourth embodiment of the present invention;

FIG. 23 shows a fifth step of the method of manufacturing a semiconductor microstructure in accordance with the fourth embodiment of the present invention;

FIG. 24 shows a sixth step of the method of manufacturing a semiconductor microstructure in accordance with the fourth embodiment of the present invention;

FIG. 25 shows a seventh step of the method of manufacturing a semiconductor microstructure in accordance with the fourth embodiment of the present invention;

FIG. 26 shows a first step of a method of manufacturing a semiconductor microstructure in accordance with a fifth embodiment of the present invention;

FIG. 27 shows a second step of the method of manufacturing a semiconductor microstructure in accordance with the fifth embodiment of the present invention;

FIG. 28 shows a third step of the method of manufacturing a semiconductor microstructure in accordance with the fifth embodiment of the present invention;

FIG. 29 shows a fourth step of the method of manufacturing a semiconductor microstructure in accordance with the fifth embodiment of the present invention;

FIG. 30 shows a fifth step of the method of manufacturing a semiconductor microstructure in accordance with the fifth embodiment of the present invention;

FIG. 31 shows a sixth step of the method of manufacturing a semiconductor microstructure in accordance with the fifth embodiment of the present invention;

FIG. 32 shows a seventh step of the method of manufacturing a semiconductor microstructure in accordance with the fifth embodiment of the present invention;

FIG. 33 shows an eighth step of the method of manufacturing a semiconductor microstructure in accordance with the fifth embodiment of the present invention;

FIG. 34 shows a ninth step of the method of manufacturing a semiconductor microstructure in accordance with the fifth embodiment of the present invention;

FIG. 35 shows a tenth step of the method of manufacturing a semiconductor microstructure in accordance with the fifth embodiment of the present invention;

FIG. 36 shows a first step of a method of manufacturing a semiconductor microstructure in accordance with a sixth embodiment of the present invention;

FIG. 37 shows a second step of the method of manufacturing a semiconductor microstructure in accordance with the sixth embodiment of the present invention;

FIG. 38 shows a third step of the method of manufacturing a semiconductor microstructure in accordance with the sixth embodiment of the present invention;

FIG. 39 shows a fourth step of the method of manufacturing a semiconductor microstructure in accordance with the sixth embodiment of the present invention;

FIG. 40 shows a fifth step of the method of manufacturing a semiconductor microstructure in accordance with the sixth embodiment of the present invention;

FIG. 41 shows a sixth step of the method of manufacturing a semiconductor microstructure in accordance with the sixth embodiment of the present invention; and

FIG. 42 shows a seventh step of the method of manufacturing a semiconductor microstructure in accordance with the sixth embodiment of the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

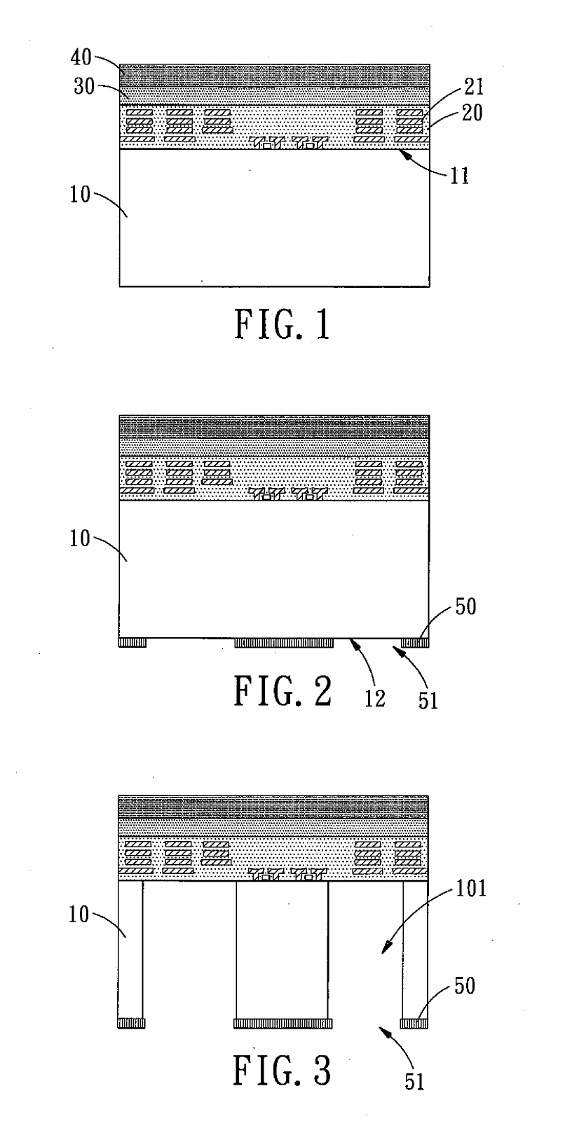

Referring to FIGS. 1-5, a method of manufacturing a semiconductor microstructure in accordance with an embodiment of the present invention is illustrated and comprises the steps of:

As shown in FIG. 1, firstly forming a standard CMOS wafer 20 with at least one micro-electro-mechanical structure 21 on the top surface 11 of a silicon substrate 10, and forming a sacrificial layer 30 and a resist layer 40 sequentially on the top surface of the CMOS wafer 20;

As shown in FIG. 2, forming an etching resist layer 50 on a lower rear surface 12 of the silicon substrate 10, and the opening 51 of the etching resist layer 50 opens toward the micro-electro-mechanical structure 21;

As shown in FIG. 3, etching the lower rear surface 12 of the silicon substrate 10 with a DRIE (deep reactive ion etching) or wet etching, and forming a space 101 in the silicon substrate 10 toward the direction of the micro-electro-mechanical structure 21, and the space 101 reaches the CMOS wafer 20;

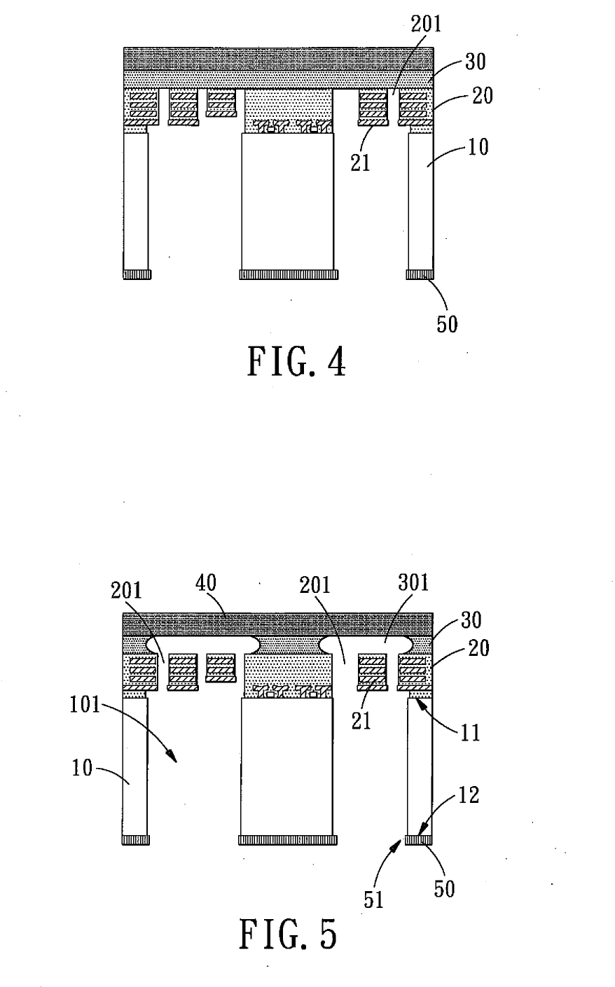

As shown in FIG. 4, using RIE (reactive ion etching) to directionally etch the CMOS wafer 20 from the space 101 of the silicon substrate 10 to the predetermined micro-electro-mechanical structure 21, thus forming a space 201 which reaches the sacrificial layer 30;

As shown in FIG. 5, anisotropic etching the sacrificial layer 30 from the space 201 of the CMOS wafer 20 to form a space 301 corresponding to the micro-electro-mechanical structure 21, thus achieving the suspension of the micro-electro-mechanical structure 21, furthermore, the top of the micro-electro-mechanical structure 21 is airtightly sealed with the resist layer 40.

With the above steps, the manufacturing method of the present invention can produce the following effects:

First, effectively preventing the undercut: DRIE (deep reactive ion etching) or wet etching the lower rear surface 12 of the silicon substrate 10 can reduce the amount of etching which causes the exposure of the micro-electro-mechanical structure 21, and with cooperation of the RIE, the undercut occurrences can be prevented effectively.

Second, reducing the exposure and possibility of damage of the micro-electro-mechanical structure, and effectively saving the package cost: since the lower rear surface 12 of the silicon substrate 10 is treated with DRIE, RIE and anisotropic etching, respectively, from the beginning of the etching process to the suspension, the top of the micro-electro-mechanical structure 21 of the CMOS wafer 20 is always protected with the resist layer 40, thus effective preventing the exposure of the micro-electro-mechanical structure and reducing the and possibility of damage thereof. Furthermore, the resist layer 40 on the top of the CMOS wafer 20 can directly be used as a package structure. Therefore, the present invention is saved from the complicated and high package process.

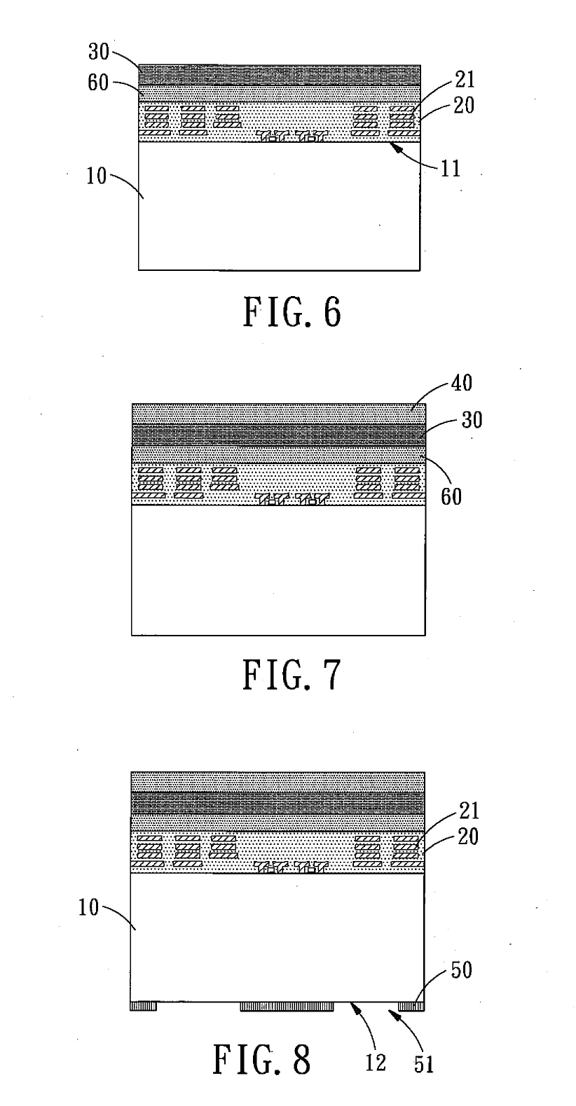

FIGS. 6-12 show a method of manufacturing a semiconductor microstructure in accordance with another embodiment of the present invention and method comprises the following steps:

As shown in FIG. 6, firstly forming a standard CMOS wafer 20 with at least one micro-electro-mechanical structure 21 on the top surface 11 of a silicon substrate 10, and forming a storing layer 60 and sacrificial layer 30 sequentially on the top surface of the CMOS wafer 20;

As shown in FIG. 7, forming a resist layer 40 on the sacrificial layer 30;

As shown in FIG. 8, forming an etching resist layer 50 on a lower rear surface 12 of the silicon substrate 10, and the opening 51 of the etching resist layer 50 opens toward the micro-electro-mechanical structure 21;

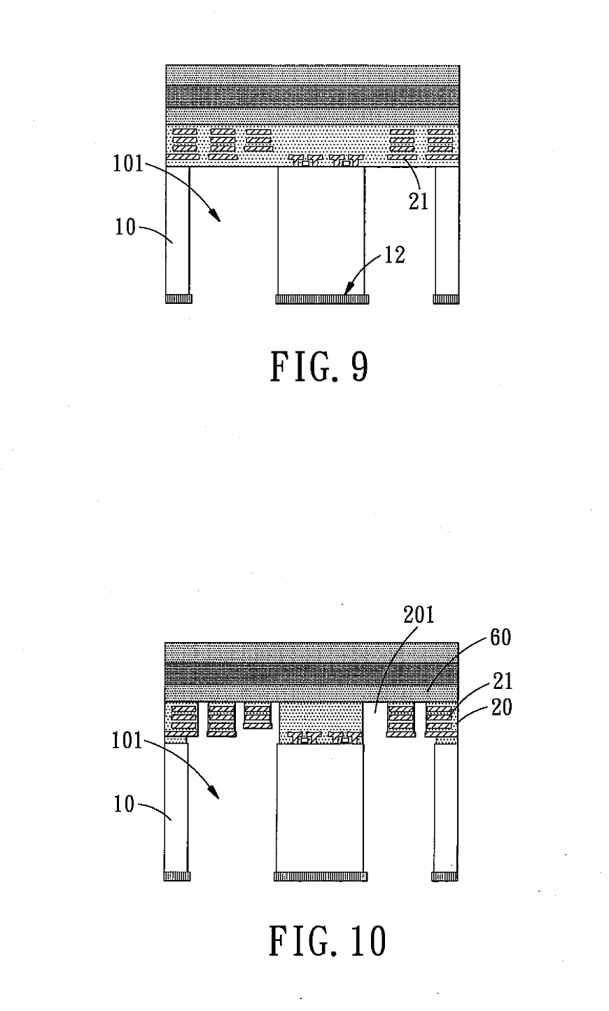

As shown in FIG. 9, etching the lower rear surface 12 of the silicon substrate 10 with a DRIE (deep reactive ion etching) or wet etching, and forming a space 101 in the silicon substrate 10 toward the direction of the micro-electro-mechanical structure 21, and the space 101 reaches the CMOS wafer 20;

As shown in FIG. 10, using RIE to directionally etch the CMOS wafer 20 from the space 101 of the silicon substrate 10 to the predetermined micro-electro-mechanical structure 21, thus forming a space 201 which reaches the storing layer 60;

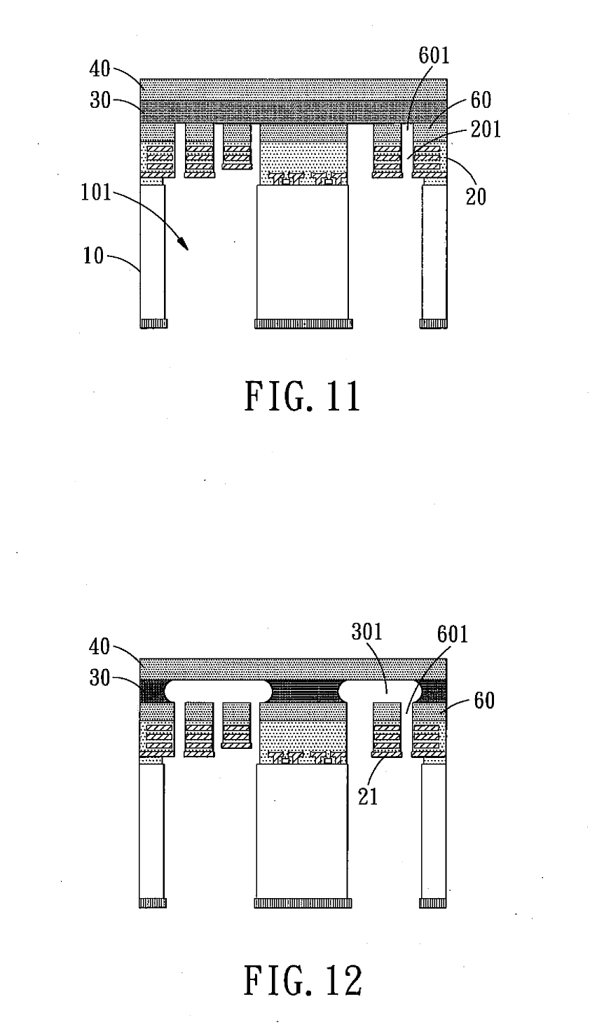

As shown in FIG. 11, using RIE or DRIE to directionally etch the storing layer 60 from the space 201 of the CMOS wafer 20 through the predetermined micro-electro-mechanical structure 21, thus forming a space 601 which reaches the sacrificial layer 30;

As shown in FIG. 12, isotropic etching the sacrificial layer 30 from the space 601 of the storing layer 60 to form a space 301 corresponding to the micro-electro-mechanical structure 21, thus achieving the suspension of the micro-electro-mechanical structure 21, at this moment, the storing layer 60 with a predetermined thickness is still left on one side of the micro-electro-mechanical structure 21 for enabling the user to adjust and control the physical characteristics (such as weight, torsion and etc) of the micro-electro-mechanical structure 21, in addition, the top of the micro-electro-mechanical structure 21 is airtightly sealed with the resist layer 40.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, using the storing layer 60 and the sacrificial layer 30 to achieve a free control of the thickness and weight of the micro-electro-mechanical structure, so that the user can adjust and control the physical characteristics (such as weight, torsion and etc) of the micro-electro-mechanical structure 21.

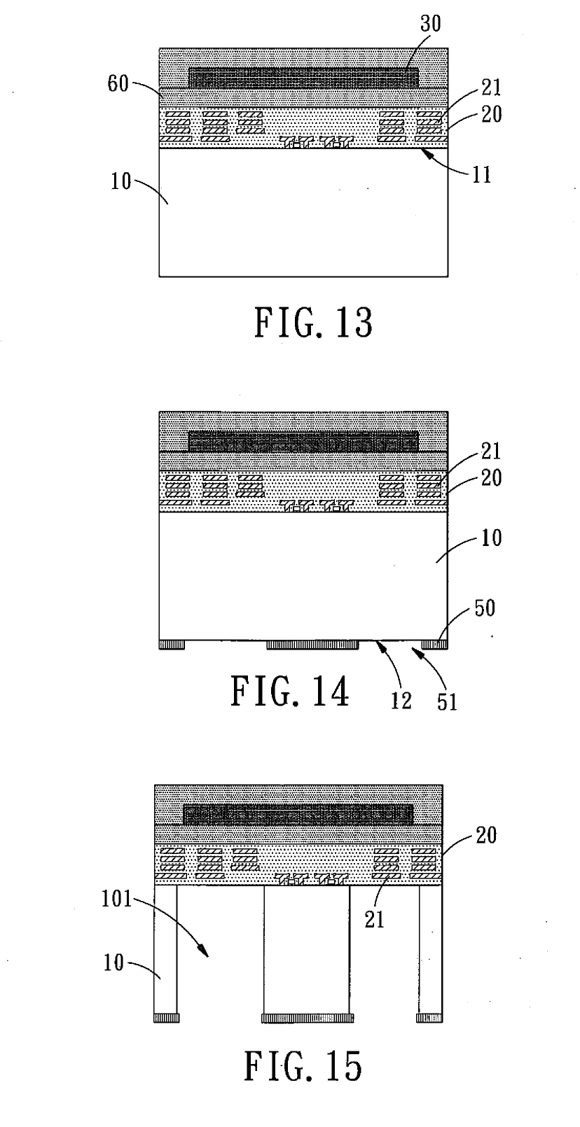

FIGS. 13-18 show a method of manufacturing a semiconductor microstructure in accordance with a third embodiment of the present invention and method comprises the following steps:

As shown in FIG. 13, firstly forming a standard CMOS wafer 20 with at least one micro-electro-mechanical structure 21 on the top surface 11 of a silicon substrate 10, forming a storing layer 60 and sacrificial layer 30 sequentially on the top surface of the CMOS wafer 20, and forming a cover-shaped resist layer 40 on the sacrificial layer 30 in such a manner that the outer edge of the resist layer 40 is in contact with the storing layer 60;

As shown in FIG. 14, forming an etching resist layer 50 on a lower rear surface 12 of the silicon substrate 10, and the opening 51 of the etching resist layer 50 opens toward the micro-electro-mechanical structure 21;

As shown in FIG. 15, etching the lower rear surface 12 of the silicon substrate 10 with a DRIE (deep reactive ion etching), and forming a space 101 in the silicon substrate 10 toward the direction of the micro-electromechanical structure 21, and the space 101 reaches the CMOS wafer 20;

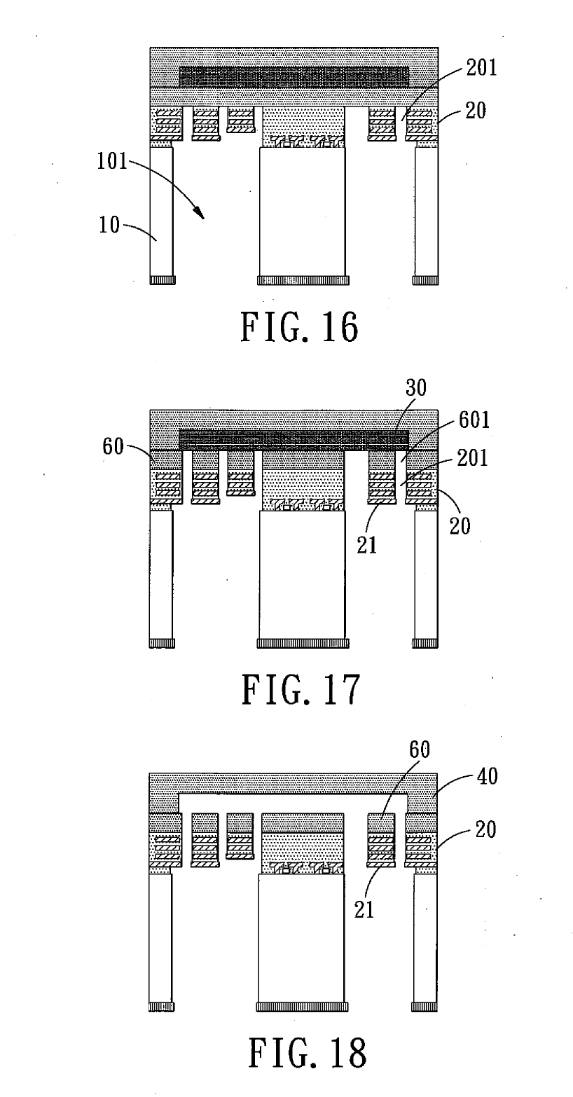

As shown in FIG. 16, using RIE to directionally etch the CMOS wafer 20 from the space 101 of the silicon substrate 10 to the predetermined micro-electro-mechanical structure 21, thus forming a space 201 which reaches the storing layer 60;

As shown in FIG. 17, using RIE or DRIE to directionally etch the storing layer 60 from the space 201 of the CMOS wafer 20 through the predetermined micro-electro-mechanical structure 21, thus forming a space 601 which reaches the sacrificial layer 30, and the space 601 is located in the range where the resist layer 40 contacts the storing layer 60;

As shown in FIG. 18, isotropic etching the sacrificial layer 30 from the space 601 of the storing layer 60 to remove all the sacrificial layer 30, thus achieving the suspension of the micro-electro-mechanical structure 21, at this moment, the storing layer 60 with a predetermined thickness is still left on one side of the micro-electro-mechanical structure 21 for enabling the user to adjust and control the physical characteristics (such as weight, torsion and etc) of the micro-electro-mechanical structure 21, in addition, the top of the micro-electro-mechanical structure 21 is airtightly sealed with the resist layer 40.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure (same as aforementioned description).

Fourth, the top of the micro-electro-mechanical structure 21 is airtightly sealed with the cover-shaped resist layer 40, which not only improves the sealing effect, and the cover-shaped resist layer 40 can directly be used as a package structure. Therefore, the present invention is saved from the complicated and high package process.

FIGS. 19-25 show a method of manufacturing a semiconductor microstructure in accordance with a fourth embodiment of the present invention and method comprises the following steps:

As shown in FIG. 19, firstly forming a standard CMOS wafer 20 with at least one micro-electro-mechanical structure 21 on the top surface 11 of a silicon substrate 10, forming a storing layer 60 and sacrificial layer 30 sequentially on the top surface of the CMOS wafer 20, forming a cover-shaped resist layer 40 on the sacrificial layer 30 in such a manner that the outer edge of the resist layer 40 is in contact with the storing layer 60, and forming an etching resist layer 50 on a lower rear surface 12 of the silicon substrate 10, and the opening 51 of the etching resist layer 50 opens toward the micro-electro-mechanical structure 21;

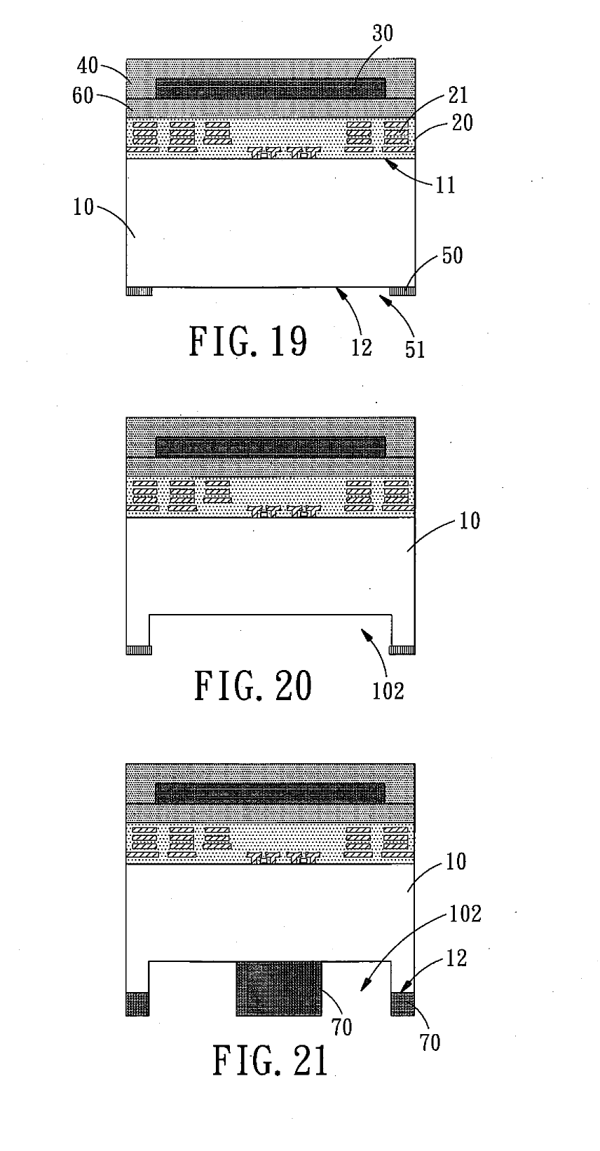

As shown in FIG. 20, directionally etching the lower rear surface 12 of the silicon substrate 10 to a predetermined height with DRIE or RIE, and forming a space 102 in the silicon substrate 10 toward the direction of the micro-electro-mechanical structure 21, and the space 102 doesn't reach the CMOS wafer 20;

As shown in FIG. 21, forming the bottom resist layer 70 on the lower rear surface 12 of the silicon substrate 10 and in the space 102 after peeling off the resist layer 50;

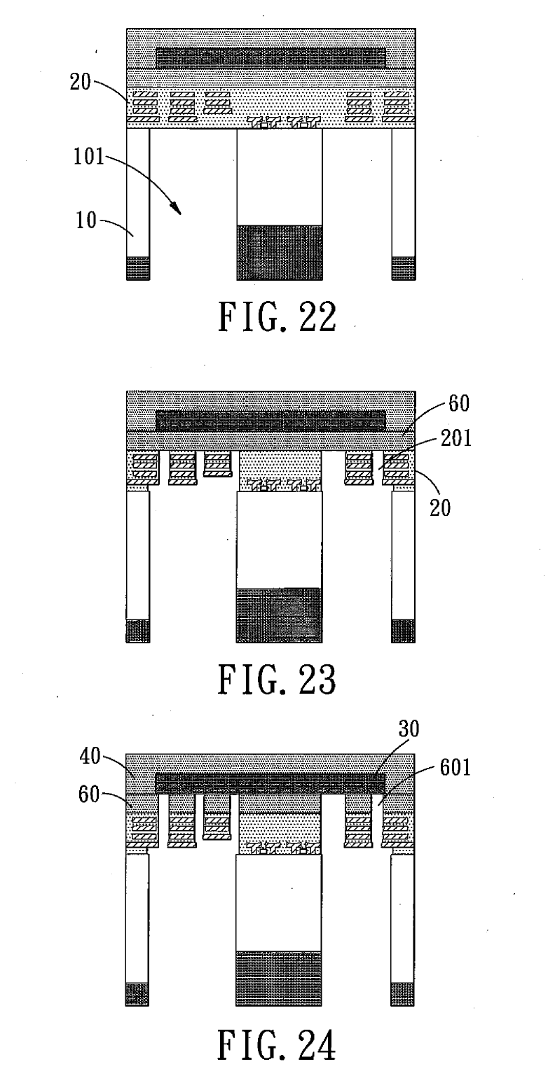

As shown in FIG. 22, taking use of the bottom resist layer 70 to etch the silicon substrate 10 with DRIE, and forming a space 101 corresponding to the micro-electro-mechanical structure 21, and the space 101 doesn't reach the CMOS wafer 20;

As shown in FIG. 23, using RIE to directionally etch the CMOS wafer 20 from the space 101 of the silicon substrate 10 to the predetermined micro-electro-mechanical structure 21, thus forming a space 201 which reaches the storing layer 60;

As shown in FIG. 24, using RIE or DRIE to directionally etch the storing layer 60 from the space 201 of the CMOS wafer 20 through the predetermined micro-electro-mechanical structure 21, thus forming a space 601 which reaches the sacrificial layer 30, and the space 601 is located in the range where the resist layer 40 contacts the storing layer 60;

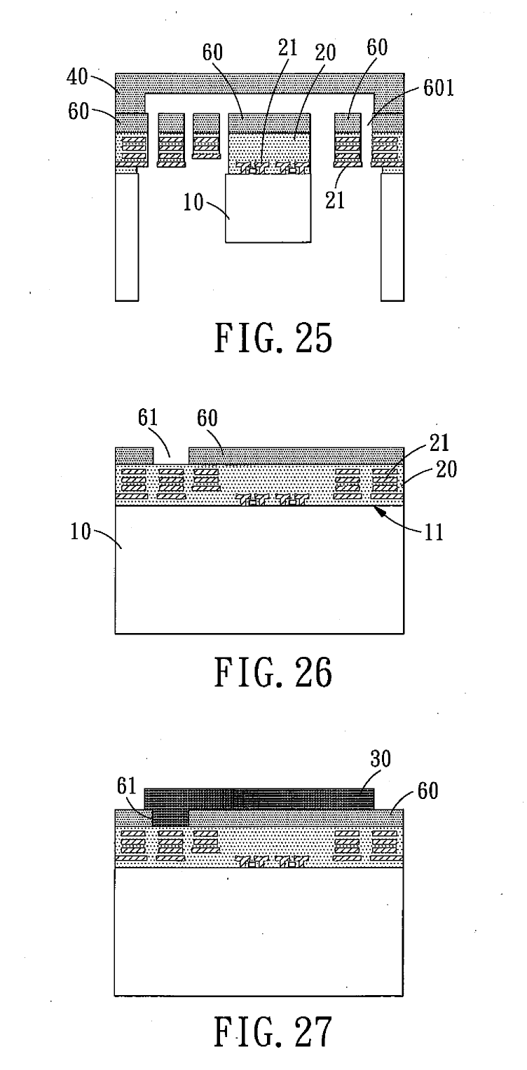

As shown in FIG. 25, isotropic etching the sacrificial layer 30 from the space 601 of the storing layer 60 to remove all the sacrificial layer 30, thus achieving the suspension of the micro-electro-mechanical structure 21, at this moment, the storing layer 60 with a predetermined thickness is still left on one side of the micro-electro-mechanical structure 21, the other side of the micro-electro-mechanical structure 21 is also covered with the silicon substrate 10 which serves as the base of weight and thickness of the micro-electro-mechanical structure 21, thus enabling the user to adjust and control the physical characteristics (such as weight, torsion and etc) of the micro-electro-mechanical structure 21, in addition, the top of the micro-electro-mechanical structure 21 is airtightly sealed with the resist layer 40.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure, furthermore, the silicon substrate 10 can also be used as the base of weight and thickness of the micro-electro-mechanical structure 21 and can increase the variable thickness and weight range of the micro-electro-mechanical structure 21.

Fourth, improving the sealing effect ((same as aforementioned description).

FIGS. 26-35 show a method of manufacturing a semiconductor microstructure in accordance with a fifth embodiment of the present invention and method comprises the following steps:

As shown in FIG. 26, firstly forming a standard CMOS wafer 20 with at least one micro-electro-mechanical structure 21 on the top surface 11 of a silicon substrate 10, forming a storing layer 60 on the top surface of the CMOS wafer 20, the storing layer 60 is formed with holes 61 located correspondingly to the micro-electro-mechanical structure 21;

As shown in FIG. 27, forming a sacrificial layer 30 on the storing layer 60, and the sacrificial layer 30 is filled in the holes 61 of the storing layer 60;

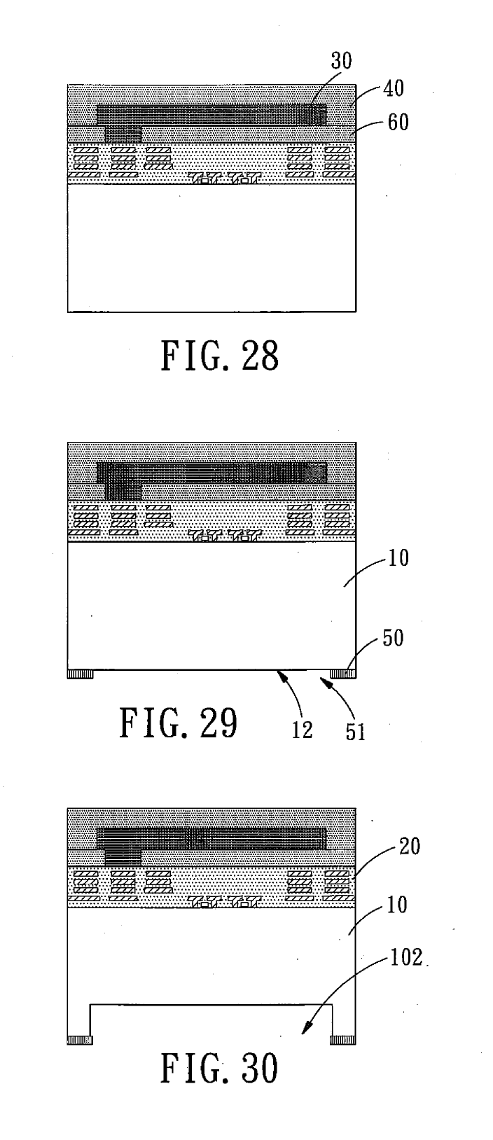

As shown in FIG. 28, forming a cover-shaped resist layer 40 on the sacrificial layer 30 in such a manner that the outer edge of the resist layer 40 is in contact with the storing layer 60;

As shown in FIG. 29, forming an etching resist layer 50 on a lower rear surface 12 of the silicon substrate 10, and the opening 51 of the etching resist layer 50 opens toward the micro-electro-mechanical structure 21;

As shown in FIG. 30, directionally etching the lower rear surface 12 of the silicon substrate 10 to a predetermined height with DRIE or RIE, and forming a space 102 in the silicon substrate 10 toward the direction of the micro-electro-mechanical structure 21, and the space 102 doesn't reach the CMOS wafer 20;

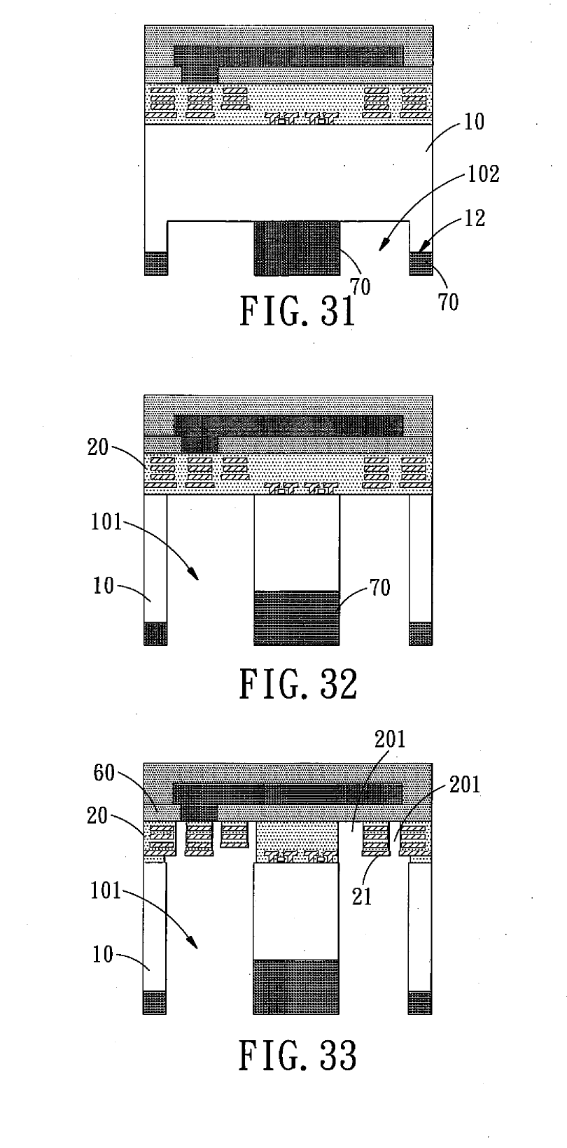

As shown in FIG. 31, forming the bottom resist layer 70 on the lower rear surface 12 of the silicon substrate 10 and in the space 102 after peeling off the resist layer 50;

As shown in FIG. 32, taking use of the bottom resist layer 70 to etch the silicon substrate 10 with DRIE, and forming a space 101 corresponding to the micro-electro-mechanical structure 21, and the space 101 doesn't reach the CMOS wafer 20;

As shown in FIG. 33, using RIE to directionally etch the CMOS wafer 20 from the space 101 of the silicon substrate 10 to the predetermined micro-electro-mechanical structure 21, thus forming a space 201 which reaches the storing layer 60;

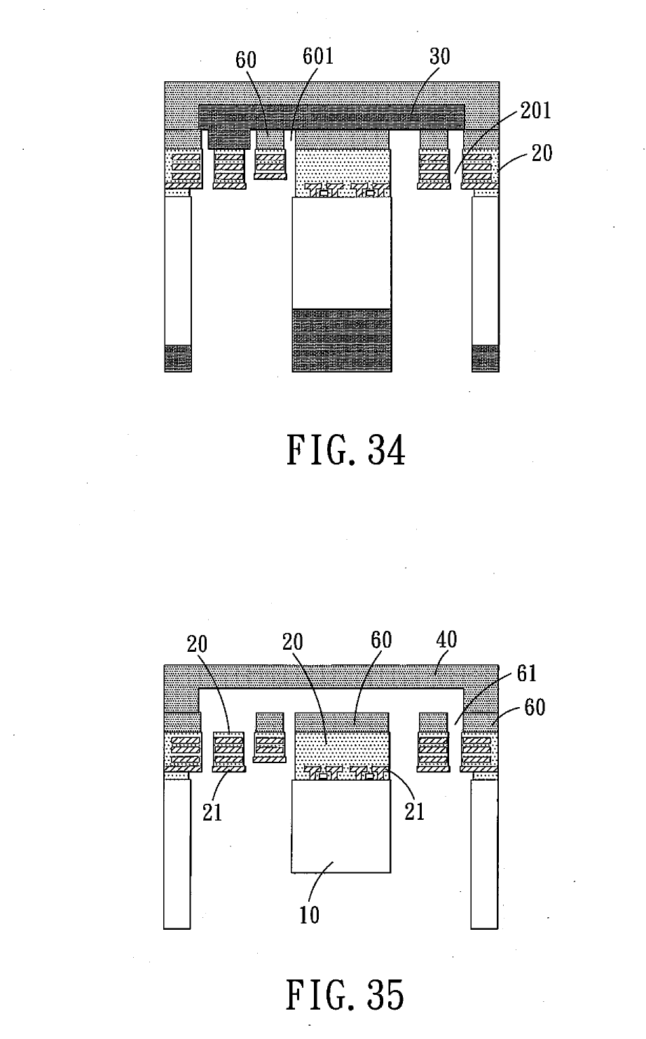

As shown in FIG. 34, using RIE or DRIE to directionally etch the storing layer 60 from the space 201 of the CMOS wafer 20 through the predetermined micro-electro-mechanical structure 21, thus forming a space 601 which reaches the sacrificial layer 30, and the space 601 is located in the range where the resist layer 40 contacts the storing layer 60 and reaches the sacrificial layer 30 in the holes 61 of the storing layer 60;

As shown in FIG. 35, isotropic etching the sacrificial layer 30 from the space 601 of the storing layer 60 to remove all the sacrificial layer 30, including the sacrificial layer 30 in the holes 61 of the storing layer 60, thus achieving the suspension of the micro-electro-mechanical structure 21, at this moment, the storing layer 60 with a predetermined thickness is still left on one side of the micro-electro-mechanical structure 21, the other side of the micro-electro-mechanical structure 21 is also covered with the silicon substrate 10 which serves as the base of weight and thickness of the micro-electro-mechanical structure 21, thus enabling the user to adjust and control the physical characteristics (such as weight, torsion and etc) of the micro-electro-mechanical structure 21, in addition, the top of the micro-electro-mechanical structure 21 is airtightly sealed with the resist layer 40, the top of the micro-electro-mechanical structure 21 originally corresponding to the holes 61 of the storing layer 60 is empty.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure, furthermore, the silicon substrate 10 can also be used as the base of weight and thickness of the micro-electro-mechanical structure 21 and can increase the variable thickness and weight range of the micro-electro-mechanical structure 21.

Fourth, improving the sealing effect ((same as aforementioned description).

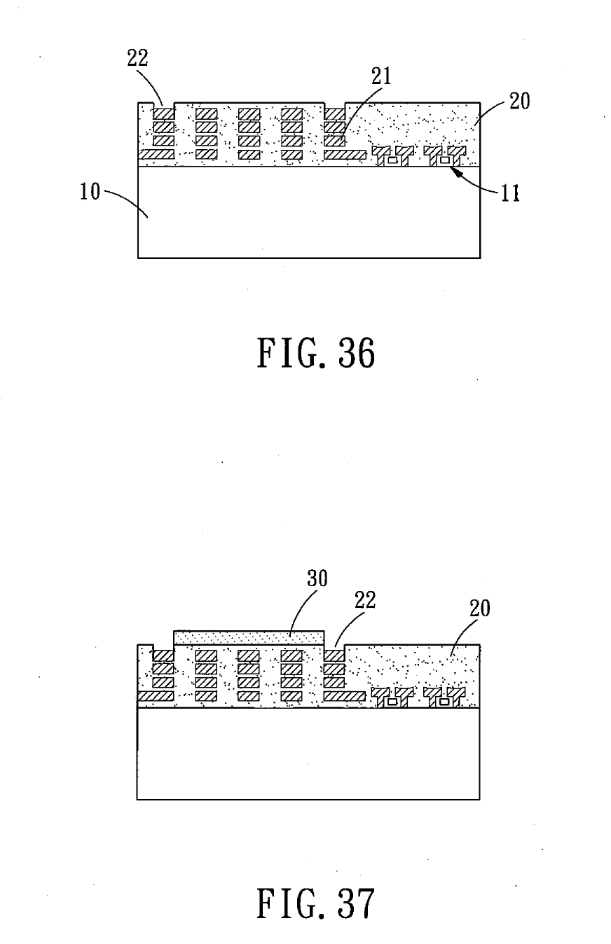

FIGS. 36-42 show a method of manufacturing a semiconductor microstructure in accordance with a fifth embodiment of the present invention and method comprises the following steps:

As shown in FIG. 36, firstly forming a standard CMOS wafer 20 with at least one micro-electro-mechanical structure 21 on the top surface 11 of a silicon substrate 10, forming a plurality of holes 22 in the top surface of the CMOS wafer 20, the holes 22 are located correspondingly to the micro-electro-mechanical structure 21;

As shown in FIG. 37, forming a sacrificial layer 30 on the storing layer 60, and the sacrificial layer 30 doesn't cover the holes 22;

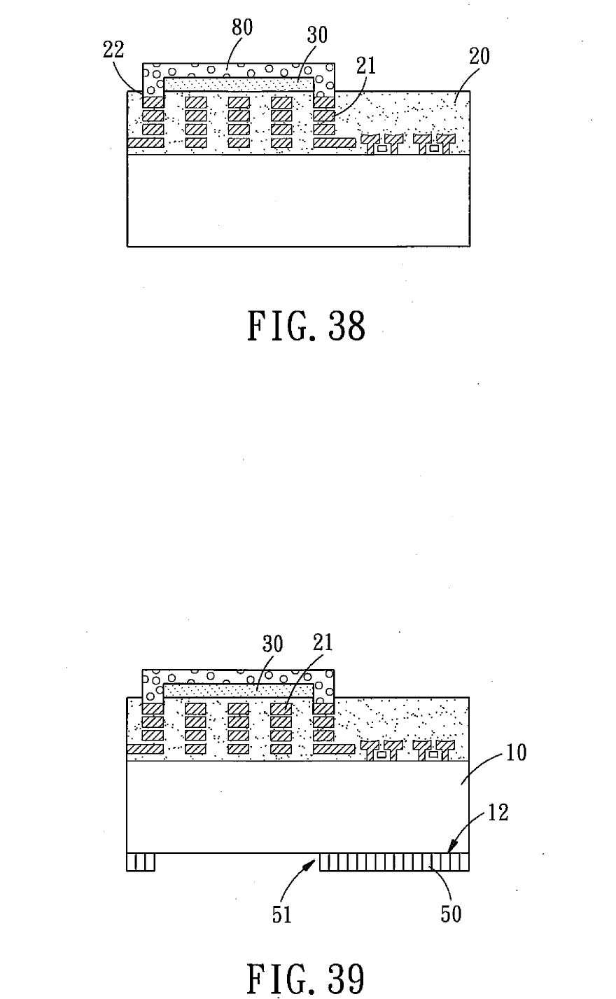

As shown in FIG. 38, forming a cover-shaped conductor resist layer 80 on the sacrificial layer 30 in such a manner that the outer edge of the conductor resist layer 80 is in contact with the storing layer 60, the conductor resist layer 80 enters the holes 22 of the CMOS wafer 20 and is electrically connected to the micro-electro-mechanical structure 21, the conductor resist layer 80 can be made of high conductivity metal, including aluminum, nickel, silver, copper, or gold.

As shown in FIG. 39, forming an etching resist layer 50 on a lower rear surface 12 of the silicon substrate 10, and the opening 51 of the etching resist layer 50 opens toward the micro-electro-mechanical structure 21;

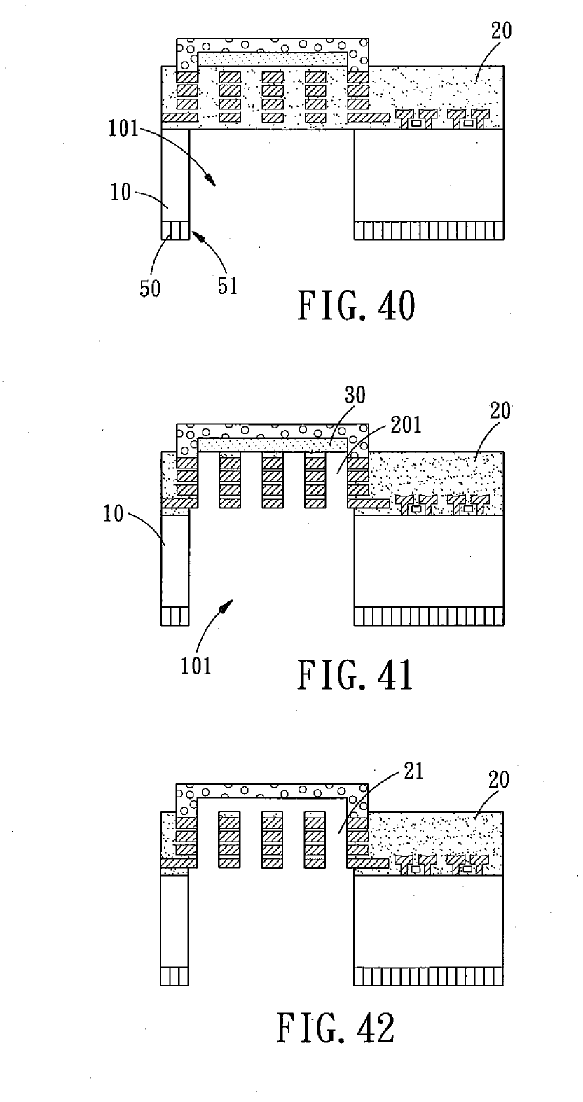

As shown in FIG. 40, directionally etching the lower rear surface 12 of the silicon substrate 10 with DRIE, and forming a space 101 in the silicon substrate 10, and the space 101 reaches the CMOS wafer 20;

As shown in FIG. 41, using RIE to directionally etch the CMOS wafer 20 from the space 101 of the silicon substrate 10 to the predetermined micro-electro-mechanical structure 21, thus forming a space 201 which reaches the sacrificial layer 30;

As shown in FIG. 42, etching the sacrificial layer 30 from the space 201 of the micro-electro-mechanical structure 21 to remove all the sacrificial layer, thus achieving the suspension of the micro-electro-mechanical structure 21, at this moment, the conductor resist layer 80 can allow electric connection to at least two micro-electro-mechanical structures 21 and airtightly seals the top of the micro-electro-mechanical structures 21.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure (same as aforementioned description).

Fourth, improving the sealing effect ((same as aforementioned description).

Fifth, the conductor resist layer 80 can be used to allow electric connection to at least two micro-electro-mechanical structures 21 without affecting the original design of the micro-electro-mechanical structure.

To summarize, a method of manufacturing a semiconductor microstructure in accordance with the present invention and method comprises the steps of: forming a sacrificial layer and a resist layer sequentially on the top surface of a standard CMOS wafer; forming an etching resist layer on the lower rear surface of the silicon substrate; etching the lower rear surface of the silicon substrate with deep reactive ion etching to form a space corresponding to the micro-electro-mechanical structure; and etching the standard CMOS wafer and the sacrificial layer, respectively to cause the suspension of the micro-electro-mechanical structure.

Such arrangements effectively prevent the undercut, reduce the exposure and possibility of damage of the micro-electro-mechanical structure, and effectively save the package cost.

While we have shown and described various embodiments in accordance with the present invention, it is clear to those skilled in the art that further embodiments may be made without departing from the scope of the present invention.

### BACKGROUND OF THE INVENTION

1. Field of the Invention

The present invention relates to a method of manufacturing a semiconductor, and more particularly to a method of manufacturing a semiconductor microstructure, in addition to causing suspension of the micro-electro-mechanical structure, this method further effectively prevents the undercut, reduces the exposure and possibility of damage of the micro-electro-mechanical structure, and effectively saves the package cost.

2. Description of the Prior Art

The existing semiconductor micro-electro-mechanical system includes various micro-electro-mechanical structures, such as: unmovable probe, flow passage, cavity structure, or some other structures, like moveable springs, linkage, gears (rigid motion or flexible deformation), etc.

Various semiconductor applications can be formed by incorporating the above various structures into relative semiconductor circuits. Hence, how to improve the various functions of the micro mechanical structures with the manufacturing methods is the key point of the future semiconductor micro-electro-mechanical system and is also the toughest challenge in further researching the chip. The development potential will be inestimable if the manufacturing method is improved.

The existing method of manufacturing the micro-electro-mechanical sensing device and the starter usually needs to make a suspension structure on a silicon substrate, and the manufacturing process must adopt advanced semiconductor technology, such as the dry etching of high-aspect-ratio structure and sacrificial-layer in MEMS (micro-electro-mechanical systems).

The conventional technologies, such as the one disclosed in U.S. Pat. No. 6,458,615B1, are usually to form a standard CMOS (Complementary Metal-Oxide Semiconductor) wafer with at least one micro-electro-mechanical structure on the top surface of the silicon substrate, and then the etching is processed layer by layer from top surface. After the side edge of the micro-electro-mechanical structure is etched, isotropic etching is carried out to etch the silicon substrate, thus causing the suspension of the micro-electro-mechanical structure.

The above conventional method can manufacture the suspended micro-electro-mechanical structure, however, it also has the following disadvantages:

First, it adopts anisotropic dry chemical etching and uses chemical reaction to remove the isolation layer, however, after the side edge of the micro-electro-mechanical structure is etched, the silicon substrate still needs to be massively etched by isotropic chemical etching, and this technique will produce serious undercut problems.

Second, the micro-electro-mechanical structure is always exposed to the manufacturing process of this conventional technology, and after the long time of multi-layer processing, the micro-electro-mechanical structure is likely to be dirtied or damaged, leading to a low yield of good products.

Third, after etching process is finished, the micro-electro-mechanical structure can already be suspended, special means is required to hermetically package the surface of the micro-electro-mechanical structure. However, the micro-electro-mechanical structure must be ensured in a suspended state. The conventional method is to use a special cap to cover the surface of the product, and then precisely make a package film without touching the micro-electro-mechanical structure, and this package technology is complicated and high cost and is incompatible with the IC (integrated circuit) package technology.

To solve the disadvantages, U.S. Pat. No. 6,712,983 B2 discloses a Reactive Ion Etching technology which substantially reduces the occurrences of undercut. However, its etching is also carried out layer by layer from the top downward, the last one etching of the silicon substrate can only be performed by using horizontal etching technology. Hence, this improved conventional technology is still complicated and troublesome, and the micro-electro-mechanical structure still has the problem of undercut after massive etching and horizontal etching. Furthermore, the problems of the exposure of the micro-electro-mechanical structure and being not good for later packaging have still not been improved.

The present invention has arisen to mitigate and/or obviate the afore-described disadvantages.

### SUMMARY OF THE INVENTION

The primary objective of the present invention is to provide a method of manufacturing a semiconductor microstructure which effectively prevents the occurrence of undercut.

To achieve the above objective, a method of manufacturing a semiconductor microstructure provided by the present invention comprises: forming a standard CMOS wafer with at least one micro-electro-mechanical structure on a top surface of a silicon substrate, forming at least one sacrificial layer and one resist layer sequentially on the top surface of the CMOS wafer; forming an etching resist layer on a lower rear surface of the silicon substrate, etching the lower rear surface of the silicon base by deep reactive ion etching or wet etching to form a space corresponding to the micro-electro-mechanical structure, and etching the CMOS wafer and the sacrificial layer, respectively, to cause suspension of the micro-electro-mechanical structure.

Etching the lower rear surface of the silicon substrate by deep reactive ion etching can reduce the time of etching the micro-electro-mechanical structure and reduce the amount of undercut, and by cooperating with the technology of deep reactive ion etching and reactive ion etching, the micro-electro-mechanical structure can be effectively prevented from undercutting.

The secondary objective of the present invention is to provide a method of manufacturing a semiconductor microstructure which effectively prevents the undercut, reduces the exposure and possibility of damage of the micro-electro-mechanical structure, and effectively saves the package cost.

To achieve the above objective, a method of manufacturing a semiconductor microstructure provided by the present invention comprises: forming at least one sacrificial layer and one resist layer sequentially on the top surface of the CMOS wafer; etching the lower rear surface of the silicon base by deep reactive ion etching to form a space corresponding to the micro-electro-mechanical structure, and etching the CMOS wafer and the sacrificial layer, respectively, to cause suspension of the micro-electro-mechanical structure, and the top of the micro-electro-mechanical structure is still sealed with the resist layer.

With the unique technology of etching the lower rear surface of the silicon substrate by deep reactive ion etching, from the beginning of the etching process to the suspension, the top of the micro-electro-mechanical structure of the CMOS wafer is always protected with the resist layer, thus effective preventing the exposure of the micro-electro-mechanical structure and reducing the and possibility of damage thereof.

It is more important that since the resist layer on the top surface of the CMOS wafer can directly be used as a package structure for sealing the micro-electro-mechanical structure. Therefore, the present invention is saved from the complicated and high package process.

Another objective of the present invention is to provide a method of manufacturing a semiconductor microstructure which can freely control the thickness and weight of the micro-electro-mechanical structure or make the conductor resist layer, thus effectively increasing the patterns of the micro-electro-mechanical structure while reducing the cost.

To achieve this objective, since the sacrificial layer is the last layer to be etched, the present invention utilizes plural storing layers and the sacrificial layer to adjust the thickness and weight of the micro-electro-mechanical structure. Furthermore, the resist layer will become a hollow package. And the micro-electro-mechanical structure can be electrically connected if the conductor resist layer is adopted.

The conductor resist layer can be made of high conductivity metal, including aluminum, nickel, silver, copper, or gold and is directly electrically connected to the micro-electro-mechanical structure.

It is noted that deep reactive ion etching is an anisotropic etching technology which is recognized as a very important etching technology in recent years, which utilizes the protection layer formed during the etching process to prevent the undercut problem. Therefore, etched structure and shape is free of the influence of the lattice plane and don't have convex corner and undercut. Hence, it can be etched into various shaped holes or convex blocks. In addition, with the reactive ion etching lag, the surface of the substrate can be etched to have different heights.

However, the conventional dry deep etching technology don't have the effect of convex corner and undercut, therefore, it is difficult to make a suspended micro-electro-mechanical structure. The present invention can reduce the difficulties of manufacturing a suspended micro-electro-mechanical structure by using the special technology of reverted etching.

### BRIEF DESCRIPTION OF THE DRAWINGS

FIG. 1 shows a first step of a method of manufacturing a semiconductor microstructure in accordance with a first embodiment of the present invention;

FIG. 2 shows a second step of the method of manufacturing a semiconductor microstructure in accordance with the first embodiment of the present invention;

FIG. 3 shows a third step of the method of manufacturing a semiconductor microstructure in accordance with the first embodiment of the present invention;

FIG. 4 shows a fourth step of the method of manufacturing a semiconductor microstructure in accordance with the first embodiment of the present invention;

FIG. 5 shows a fifth step of the method of manufacturing a semiconductor microstructure in accordance with the first embodiment of the present invention;

FIG. 6 shows a first step of a method of manufacturing a semiconductor microstructure in accordance with a second embodiment of the present invention;

FIG. 7 shows a second step of the method of manufacturing a semiconductor microstructure in accordance with the second embodiment of the present invention;

FIG. 8 shows a third step of the method of manufacturing a semiconductor microstructure in accordance with the second embodiment of the present invention;

FIG. 9 shows a fourth step of the method of manufacturing a semiconductor microstructure in accordance with the second embodiment of the present invention;

FIG. 10 shows a fifth step of the method of manufacturing a semiconductor microstructure in accordance with the second embodiment of the present invention;

FIG. 11 shows a sixth step of the method of manufacturing a semiconductor microstructure in accordance with the second embodiment of the present invention;

FIG. 12 shows a seventh step of the method of manufacturing a semiconductor microstructure in accordance with the second embodiment of the present invention;

FIG. 13 shows a first step of a method of manufacturing a semiconductor microstructure in accordance with a third embodiment of the present invention;

FIG. 14 shows a second step of the method of manufacturing a semiconductor microstructure in accordance with the third embodiment of the present invention;

FIG. 15 shows a third step of the method of manufacturing a semiconductor microstructure in accordance with the third embodiment of the present invention;

FIG. 16 shows a fourth step of the method of manufacturing a semiconductor microstructure in accordance with the third embodiment of the present invention;

FIG. 17 shows a fifth step of the method of manufacturing a semiconductor microstructure in accordance with the third embodiment of the present invention;

FIG. 18 shows a sixth step of the method of manufacturing a semiconductor microstructure in accordance with the third embodiment of the present invention;

FIG. 19 shows a first step of a method of manufacturing a semiconductor microstructure in accordance with a fourth embodiment of the present invention;

FIG. 20 shows a second step of the method of manufacturing a semiconductor microstructure in accordance with the fourth embodiment of the present invention;

FIG. 21 shows a third step of the method of manufacturing a semiconductor microstructure in accordance with the fourth embodiment of the present invention;

FIG. 22 shows a fourth step of the method of manufacturing a semiconductor microstructure in accordance with the fourth embodiment of the present invention;

FIG. 23 shows a fifth step of the method of manufacturing a semiconductor microstructure in accordance with the fourth embodiment of the present invention;

FIG. 24 shows a sixth step of the method of manufacturing a semiconductor microstructure in accordance with the fourth embodiment of the present invention;

FIG. 25 shows a seventh step of the method of manufacturing a semiconductor microstructure in accordance with the fourth embodiment of the present invention;

FIG. 26 shows a first step of a method of manufacturing a semiconductor microstructure in accordance with a fifth embodiment of the present invention;

FIG. 27 shows a second step of the method of manufacturing a semiconductor microstructure in accordance with the fifth embodiment of the present invention;

FIG. 28 shows a third step of the method of manufacturing a semiconductor microstructure in accordance with the fifth embodiment of the present invention;

FIG. 29 shows a fourth step of the method of manufacturing a semiconductor microstructure in accordance with the fifth embodiment of the present invention;

FIG. 30 shows a fifth step of the method of manufacturing a semiconductor microstructure in accordance with the fifth embodiment of the present invention;

FIG. 31 shows a sixth step of the method of manufacturing a semiconductor microstructure in accordance with the fifth embodiment of the present invention;

FIG. 32 shows a seventh step of the method of manufacturing a semiconductor microstructure in accordance with the fifth embodiment of the present invention;

FIG. 33 shows an eighth step of the method of manufacturing a semiconductor microstructure in accordance with the fifth embodiment of the present invention;

FIG. 34 shows a ninth step of the method of manufacturing a semiconductor microstructure in accordance with the fifth embodiment of the present invention;

FIG. 35 shows a tenth step of the method of manufacturing a semiconductor microstructure in accordance with the fifth embodiment of the present invention;

FIG. 36 shows a first step of a method of manufacturing a semiconductor microstructure in accordance with a sixth embodiment of the present invention;

FIG. 37 shows a second step of the method of manufacturing a semiconductor microstructure in accordance with the sixth embodiment of the present invention;

FIG. 38 shows a third step of the method of manufacturing a semiconductor microstructure in accordance with the sixth embodiment of the present invention;

FIG. 39 shows a fourth step of the method of manufacturing a semiconductor microstructure in accordance with the sixth embodiment of the present invention;

FIG. 40 shows a fifth step of the method of manufacturing a semiconductor microstructure in accordance with the sixth embodiment of the present invention;

FIG. 41 shows a sixth step of the method of manufacturing a semiconductor microstructure in accordance with the sixth embodiment of the present invention; and

FIG. 42 shows a seventh step of the method of manufacturing a semiconductor microstructure in accordance with the sixth embodiment of the present invention.

### DETAILED DESCRIPTION OF THE PREFERRED EMBODIMENTS

The present invention will be clearer from the following description when viewed together with the accompanying drawings, which show, for purpose of illustrations only, the preferred embodiment in accordance with the present invention.

Referring to FIGS. 1-5, a method of manufacturing a semiconductor microstructure in accordance with an embodiment of the present invention is illustrated and comprises the steps of:

As shown in FIG. 1, firstly forming a standard CMOS wafer 20 with at least one micro-electro-mechanical structure 21 on the top surface 11 of a silicon substrate 10, and forming a sacrificial layer 30 and a resist layer 40 sequentially on the top surface of the CMOS wafer 20;

As shown in FIG. 2, forming an etching resist layer 50 on a lower rear surface 12 of the silicon substrate 10, and the opening 51 of the etching resist layer 50 opens toward the micro-electro-mechanical structure 21;

As shown in FIG. 3, etching the lower rear surface 12 of the silicon substrate 10 with a DRIE (deep reactive ion etching) or wet etching, and forming a space 101 in the silicon substrate 10 toward the direction of the micro-electro-mechanical structure 21, and the space 101 reaches the CMOS wafer 20;

As shown in FIG. 4, using RIE (reactive ion etching) to directionally etch the CMOS wafer 20 from the space 101 of the silicon substrate 10 to the predetermined micro-electro-mechanical structure 21, thus forming a space 201 which reaches the sacrificial layer 30;

As shown in FIG. 5, isotropic etching the sacrificial layer 30 from the space 201 of the CMOS wafer 20 to form a space 301 corresponding to the micro-electro-mechanical structure 21, thus achieving the suspension of the micro-electro-mechanical structure 21, furthermore, the top of the micro-electro-mechanical structure 21 is hermetically sealed with the resist layer 40.

With the above steps, the manufacturing method of the present invention can produce the following effects:

First, effectively preventing the undercut: DRIE (deep reactive ion etching) or wet etching the lower rear surface 12 of the silicon substrate 10 can reduce the amount of etching which causes the exposure of the micro-electro-mechanical structure 21, and with cooperation of the RIE, the undercut occurrences can be prevented effectively.

Second, reducing the exposure and possibility of damage of the micro-electro-mechanical structure, and effectively saving the package cost: since the lower rear surface 12 of the silicon substrate 10 is treated with DRIE, RIE and isotropic etching, respectively, from the beginning of the etching process to the suspension, the top of the micro-electro-mechanical structure 21 of the CMOS wafer 20 is always protected with the resist layer 40, thus effectively preventing the exposure of the micro-electro-mechanical structure and reducing the and possibility of damage thereof. Furthermore, the resist layer 40 on the top of the CMOS wafer 20 can directly be used as a standard package process. Therefore, the present invention is saved from the complicated and high package process.

FIGS. 6-12 show a method of manufacturing a semiconductor microstructure in accordance with another embodiment of the present invention and method comprises the following steps:

As shown in FIG. 6, firstly forming a standard CMOS wafer 20 with at least one micro-electro-mechanical structure 21 on the top surface 11 of a silicon substrate 10, and forming a storing layer 60 and sacrificial layer 30 sequentially on the top surface of the CMOS wafer 20;

As shown in FIG. 7, forming a resist layer 40 on the sacrificial layer 30;

As shown in FIG. 8, forming an etching resist layer 50 on a lower rear surface 12 of the silicon substrate 10, and the opening 51 of the etching resist layer 50 opens toward the micro-electro-mechanical structure 21;

As shown in FIG. 9, etching the lower rear surface 12 of the silicon substrate 10 with a DRIE (deep reactive ion etching) or wet etching, and forming a space 101 in the silicon substrate 10 toward the direction of the micro-electro-mechanical structure 21, and the space 101 reaches the CMOS wafer 20;

As shown in FIG. 10, using RIE to directionally etch the CMOS wafer 20 from the space 101 of the silicon substrate 10 to the predetermined micro-electro-mechanical structure 21, thus forming a space 201 which reaches the storing layer 60;

As shown in FIG. 11, using RIE or DRIE to directionally etch the storing layer 60 from the space 201 of the CMOS wafer 20 through the predetermined micro-electro-mechanical structure 21, thus forming a space 601 which reaches the sacrificial layer 30;

As shown in FIG. 12, isotropic etching the sacrificial layer 30 from the space 601 of the storing layer 60 to form a space 301 corresponding to the micro-electro-mechanical structure 21, thus achieving the suspension of the micro-electro-mechanical structure 21, at this moment, the storing layer 60 with a predetermined thickness is still left on one side of the micro-electro-mechanical structure 21 for enabling the user to adjust and control the physical characteristics (such as weight, torsion and etc) of the micro-electro-mechanical structure 21, in addition, the top of the micro-electro-mechanical structure 21 is hermetically sealed with the resist layer 40.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, using the storing layer 60 and the sacrificial layer 30 to achieve a free control of the thickness and weight of the micro-electro-mechanical structure, so that the user can adjust and control the physical characteristics (such as weight, torsion and etc) of the micro-electro-mechanical structure 21.

FIGS. 13-18 show a method of manufacturing a semiconductor microstructure in accordance with a third embodiment of the present invention and method comprises the following steps:

As shown in FIG. 13, firstly forming a standard CMOS wafer 20 with at least one micro-electro-mechanical structure 21 on the top surface 11 of a silicon substrate 10, forming a storing layer 60 and sacrificial layer 30 sequentially on the top surface of the CMOS wafer 20, and forming a cover-shaped resist layer 40 on the sacrificial layer 30 in such a manner that the outer edge of the resist layer 40 is in contact with the storing layer 60;

As shown in FIG. 14, forming an etching resist layer 50 on a lower rear surface 12 of the silicon substrate 10, and the opening 51 of the etching resist layer 50 opens toward the micro-electro-mechanical structure 21;

As shown in FIG. 15, etching the lower rear surface 12 of the silicon substrate 10 with a DRIE (deep reactive ion etching), and forming a space 101 in the silicon substrate 10 toward the direction of the micro-electromechanical structure 21, and the space 101 reaches the CMOS wafer 20;

As shown in FIG. 16, using RIE to directionally etch the CMOS wafer 20 from the space 101 of the silicon substrate 10 to the predetermined micro-electro-mechanical structure 21, thus forming a space 201 which reaches the storing layer 60;

As shown in FIG. 17, using RIE or DRIE to directionally etch the storing layer 60 from the space 201 of the CMOS wafer 20 through the predetermined micro-electro-mechanical structure 21, thus forming a space 601 which reaches the sacrificial layer 30, and the space 601 is located in the range where the resist layer 40 contacts the storing layer 60;

As shown in FIG. 18, isotropic etching the sacrificial layer 30 from the space 601 of the storing layer 60 to remove all the sacrificial layer 30, thus achieving the suspension of the micro-electro-mechanical structure 21, at this moment, the storing layer 60 with a predetermined thickness is still left on one side of the micro-electro-mechanical structure 21 for enabling the user to adjust and control the physical characteristics (such as weight, torsion and etc) of the micro-electro-mechanical structure 21, in addition, the top of the micro-electro-mechanical structure 21 is hermetically sealed with the resist layer 40.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure (same as aforementioned description).

Fourth, the top of the micro-electro-mechanical structure 21 is hermetically sealed with the cover-shaped resist layer 40, which not only improves the sealing effect, and the cover-shaped resist layer 40 can directly be used as a standard package process. Therefore, the present invention is saved from the complicated and high package process.

FIGS. 19-25 show a method of manufacturing a semiconductor microstructure in accordance with a fourth embodiment of the present invention and method comprises the following steps:

As shown in FIG. 19, firstly forming a standard CMOS wafer 20 with at least one micro-electro-mechanical structure 21 on the top surface 11 of a silicon substrate 10, forming a storing layer 60 and sacrificial layer 30 sequentially on the top surface of the CMOS wafer 20, forming a cover-shaped resist layer 40 on the sacrificial layer 30 in such a manner that the outer edge of the resist layer 40 is in contact with the storing layer 60, and forming an etching resist layer 50 on a lower rear surface 12 of the silicon substrate 10, and the opening 51 of the etching resist layer 50 opens toward the micro-electro-mechanical structure 21;

As shown in FIG. 20, directionally etching the lower rear surface 12 of the silicon substrate 10 to a predetermined height with DRIE or RIE, and forming a space 102 in the silicon substrate 10 toward the direction of the micro-electro-mechanical structure 21, and the space 102 doesn't reach the CMOS wafer 20;

As shown in FIG. 21, forming the bottom resist layer 70 on the lower rear surface 12 of the silicon substrate 10 and in the space 102 after stripping off the resist layer 50;

As shown in FIG. 22, taking use of the bottom resist layer 70 to etch the silicon substrate 10 with DRIE, and forming a space 101 corresponding to the micro-electro-mechanical structure 21, and the space 101 reaches the CMOS wafer 20;

As shown in FIG. 23, using RIE to directionally etch the CMOS wafer 20 from the space 101 of the silicon substrate 10 to the predetermined micro-electro-mechanical structure 21, thus forming a space 201 which reaches the storing layer 60;

As shown in FIG. 24, using RIE or DRIE to directionally etch the storing layer 60 from the space 201 of the CMOS wafer 20 through the predetermined micro-electro-mechanical structure 21, thus forming a space 601 which reaches the sacrificial layer 30, and the space 601 is located in the range where the resist layer 40 contacts the storing layer 60;

As shown in FIG. 25, isotropic etching the sacrificial layer 30 from the space 601 of the storing layer 60 to remove all the sacrificial layer 30, thus achieving the suspension of the micro-electro-mechanical structure 21, at this moment, the storing layer 60 with a predetermined thickness is still left on one side of the micro-electro-mechanical structure 21, the other side of the micro-electro-mechanical structure 21 is also covered with the silicon substrate 10 which serves as the base of weight and thickness of the micro-electro-mechanical structure 21, thus enabling the user to adjust and control the physical characteristics (such as weight, torsion and etc) of the micro-electro-mechanical structure 21, in addition, the top of the micro-electro-mechanical structure 21 is hermetically sealed with the resist layer 40.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure, furthermore, the silicon substrate 10 can also be used as the base of weight and thickness of the micro-electro-mechanical structure 21 and can increase the variable thickness and weight range of the micro-electro-mechanical structure 21.

Fourth, improving the sealing effect (same as aforementioned description).

FIGS. 26-35 show a method of manufacturing a semiconductor microstructure in accordance with a fifth embodiment of the present invention and method comprises the following steps:

As shown in FIG. 26, firstly forming a standard CMOS wafer 20 with at least one micro-electro-mechanical structure 21 on the top surface 11 of a silicon substrate 10, forming a storing layer 60 on the top surface of the CMOS wafer 20, the storing layer 60 is formed with holes 61 located correspondingly to the micro-electro-mechanical structure 21;

As shown in FIG. 27, forming a sacrificial layer 30 on the storing layer 60, and the sacrificial layer 30 is filled in the holes 61 of the storing layer 60;

As shown in FIG. 28, forming a cover-shaped resist layer 40 on the sacrificial layer 30 in such a manner that the outer edge of the resist layer 40 is in contact with the storing layer 60;

As shown in FIG. 29, forming an etching resist layer 50 on a lower rear surface 12 of the silicon substrate 10, and the opening 51 of the etching resist layer 50 opens toward the micro-electro-mechanical structure 21;

As shown in FIG. 30, directionally etching the lower rear surface 12 of the silicon substrate 10 to a predetermined height with DRIE or RE, and forming a space 102 in the silicon substrate 10 toward the direction of the micro-electro-mechanical structure 21, and the space 102 doesn't reach the CMOS wafer 20;

As shown in FIG. 31, forming the bottom resist layer 70 on the lower rear surface 12 of the silicon substrate 10 and in the space 102 after stripping off the resist layer 50;

As shown in FIG. 32, taking use of the bottom resist layer 70 to etch the silicon substrate 10 with DRIE, and forming a space 101 corresponding to the micro-electro-mechanical structure 21, and the space 101 reaches the CMOS wafer 20;

As shown in FIG. 33, using RIE to directionally etch the CMOS wafer 20 from the space 101 of the silicon substrate 10 to the predetermined micro-electro-mechanical structure 21, thus forming a space 201 which reaches the storing layer 60;

As shown in FIG. 34, using RIE or DRIE to directionally etch the storing layer 60 from the space 201 of the CMOS wafer 20 through the predetermined micro-electro-mechanical structure 21, thus forming a space 601 which reaches the sacrificial layer 30, and the space 601 is located in the range where the resist layer 40 contacts the storing layer 60 and reaches the sacrificial layer 30 in the holes 61 of the storing layer 60;

As shown in FIG. 35, isotropic etching the sacrificial layer 30 from the space 601 of the storing layer 60 to remove all the sacrificial layer 30, including the sacrificial layer 30 in the holes 61 of the storing layer 60, thus achieving the suspension of the micro-electro-mechanical structure 21, at this moment, the storing layer 60 with a predetermined thickness is still left on one side of the micro-electro-mechanical structure 21, the other side of the micro-electro-mechanical structure 21 is also covered with the silicon substrate 10 which serves as the base of weight and thickness of the micro-electro-mechanical structure 21, thus enabling the user to adjust and control the physical characteristics (such as weight, torsion and etc) of the micro-electro-mechanical structure 21, in addition, the top of the micro-electro-mechanical structure 21 is hermetically sealed with the resist layer 40, the top of the micro-electro-mechanical structure 21 originally corresponding to the holes 61 of the storing layer 60 is empty.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure, furthermore, the silicon substrate 10 can also be used as the base of weight and thickness of the micro-electro-mechanical structure 21 and can increase the variable thickness and weight range of the micro-electro-mechanical structure 21.

Fourth, improving the sealing effect (same as aforementioned description).

FIGS. 36-42 show a method of manufacturing a semiconductor microstructure in accordance with a fifth embodiment of the present invention and method comprises the following steps:

As shown in FIG. 36, firstly forming a standard CMOS wafer 20 with at least one micro-electro-mechanical structure 21 on the top surface 11 of a silicon substrate 10, forming a plurality of holes 22 in the top surface of the CMOS wafer 20, the holes 22 are located correspondingly to the micro-electro-mechanical structure 21;

As shown in FIG. 37, forming a sacrificial layer 30 on the storing layer 60, and the sacrificial layer 30 doesn't cover the holes 22;

As shown in FIG. 38, forming a cover-shaped conductor resist layer 80 on the sacrificial layer 30 in such a manner that the outer edge of the conductor resist layer 80 is in contact with the storing layer 60, the conductor resist layer 80 enters the holes 22 of the CMOS wafer 20 and is electrically connected to the micro-electro-mechanical structure 21, the conductor resist layer 80 can be made of high conductivity metal, including aluminum, nickel, silver, copper, or gold.

As shown in FIG. 39, forming an etching resist layer 50 on a lower rear surface 12 of the silicon substrate 10, and the opening 51 of the etching resist layer 50 opens toward the micro-electro-mechanical structure 21;

As shown in FIG. 40, directionally etching the lower rear surface 12 of the silicon substrate 10 with DRIE, and forming a space 101 in the silicon substrate 10, and the space 101 reaches the CMOS wafer 20;

As shown in FIG. 41, using RIE to directionally etch the CMOS wafer 20 from the space 101 of the silicon substrate 10 to the predetermined micro-electro-mechanical structure 21, thus forming a space 201 which reaches the sacrificial layer 30;

As shown in FIG. 42, etching the sacrificial layer 30 from the space 201 of the micro-electro-mechanical structure 21 to remove all the sacrificial layer, thus achieving the suspension of the micro-electro-mechanical structure 21, at this moment, the conductor resist layer 80 can allow electric connection to at least two micro-electro-mechanical structures 21 and hermetically seals the top of the micro-electro-mechanical structures 21.

With the above steps, the manufacturing method of the present invention can produce the following effects:

First, effectively preventing the undercut (same as aforementioned description).

Second, reducing the exposure and possibility of damage of the micro-electro-mechanical structure, and effectively saving the package cost (same as aforementioned description).

Third, achieving a free control of the thickness and weight of the micro-electro-mechanical structure (same as aforementioned description).

Fourth, improving the sealing effect (same as aforementioned description).

Fifth, the conductor resist layer 80 can be used to allow electric connection to at least two micro-electro-mechanical structures 21 without affecting the original design of the micro-electro-mechanical structure.

To summarize, a method of manufacturing a semiconductor microstructure in accordance with the present invention and method comprises the steps of: forming a sacrificial layer and a resist layer sequentially on the top surface of a standard CMOS wafer; forming an etching resist layer on the lower rear surface of the silicon substrate; etching the lower rear surface of the silicon substrate with deep reactive ion etching to form a space corresponding to the micro-electro-mechanical structure; and etching the standard CMOS wafer and the sacrificial layer, respectively to cause the suspension of the micro-electro-mechanical structure.

Such arrangements effectively prevent the undercut, reduce the exposure and possibility of damage of the micro-electro-mechanical structure, and effectively save the package cost.

While we have shown and described various embodiments in accordance with the present invention, it is clear to those skilled in the art that further embodiments may be made without departing from the scope of the present invention.

What is claimed is:

1. A method of manufacturing a semiconductor microstructure comprising: forming a standard CMOS wafer with at least one micro-electro-mechanical structure on a top surface of a silicon substrate, forming at least one sacrificial layer and one resist layer sequentially on the top surface of the CMOS wafer; forming an etching resist layer on a lower rear surface of the silicon substrate, etching the lower rear surface of the silicon base to form a space corresponding to the micro-electro-mechanical structure, and etching downward from the space to the resist layer, thus causing suspension of the micro-electro-mechanical structure.

2. The method of manufacturing a semiconductor microstructure as claimed in claim 1, wherein the silicon substrate is ground thin, and then the lower rear surface of the silicon substrate is etched by deep reactive ion etching or wet etching.

3. The method of manufacturing a semiconductor microstructure as claimed in claim 1, wherein an opening of the etching resist layer opens toward the micro-electro-mechanical structure, and the space of the lower rear surface of the silicon substrate reaches the CMOS wafer.

4. The method of manufacturing a semiconductor microstructure as claimed in claim 1, wherein the CMOS wafer is directionally etched to the sacrificial layer by ion etching, and the sacrificial layer is isotropic etched.

5. The method of manufacturing a semiconductor microstructure as claimed in claim 1, wherein a plurality of holes is formed in the top surface of the CMOS wafer and located correspondingly to the micro-electro-mechanical structure, the sacrificial layer on the CMOS wafer doesn't cover the holes, a conductor resist layer is formed on the sacrificial layer in such a manner that an outer edge of the conductor resist layer is in contact with the storing layer, the conductor resist layer enters the holes of the CMOS wafer and is electrically connected to the micro-electro-mechanical structure, the conductor resist layer can allow electric connection to at least two micro-electro-mechanical structures after the sacrificial layer is etched out.

6. The method of manufacturing a semiconductor microstructure as claimed in claim 1, wherein the conductor resist layer is made of one of the materials: aluminum, nickel, silver, copper, and gold.

7. A method of manufacturing a semiconductor microstructure comprising: forming a standard CMOS wafer with at least one micro-electro-mechanical structure on a top surface of a silicon substrate, forming at least one storing layer, one sacrificial layer, and one resist layer sequentially on the top surface of the CMOS wafer;
forming an etching resist layer on a lower rear surface of the silicon substrate, etching the lower rear surface of the silicon base to form a space corresponding to the micro-electro-mechanical structure;
directionally etching the CMOS wafer to the storing layer by ion etching;
directionally etching the storing layer to the sacrificial layer by deep reactive ion etching or ion etching, and the storing layer with a predetermined thickness is still left on the micro-electro-mechanical structure;
isotropic etching the sacrificial layer to cause suspension of the micro-electro-mechanical structure, the storing layer is still left on the micro-electro-mechanical structure, and a top of the micro-electro-mechanical structure is sealed with the resist layer.

8. The method of manufacturing a semiconductor microstructure as claimed in claim 7, wherein an opening of the etching resist layer opens toward the micro-electro-mechanical structure, and the space of the lower rear surface of the silicon substrate reaches the CMOS wafer.

9. The method of manufacturing a semiconductor microstructure as claimed in claim 7, wherein the resist layer is cover-shaped, and an outer edge of the conductor resist layer is in contact with the storing layer.

10. The method of manufacturing a semiconductor microstructure as claimed in claim 7, the storing layer is directionally etched by deep reactive ion etching or ion etching.

11. The method of manufacturing a semiconductor microstructure as claimed in claim 7, wherein:
a space is formed in the silicon substrate and located correspondingly to the micro-electro-mechanical structure, and the space doesn't reach the CMOS wafer;
a bottom resist layer is formed on the lower rear surface of the silicon substrate and in the space after stripping off the resist layer;
the silicon substrate is deep reactive ion etched by taking use of the bottom resist layer, and a space corresponding to the micro-electro-mechanical structure is formed by directional etching and reaches the CMOS wafer;
the silicon substrate serves as a base of weight and thickness of the micro-electro-mechanical structure after upward etching layer by layer.

12. The method of manufacturing a semiconductor microstructure as claimed in claim 9, wherein the storing layer is formed with holes located correspondingly to the micro-electro-mechanical structure, the sacrificial layer on the storing layer is filled in the holes of the storing layer, the top of the micro-electro-mechanical structure originally corresponding to the holes of the storing layer is empty after the sacrificial layer in the holes of the storing layer is etched out.

13. The method of manufacturing a semiconductor microstructure as claimed in claim 7, wherein an opening of the etching resist layer opens toward the micro-electro-mechanical structure, the lower rear surface of the silicon substrate is etched by deep reactive ion etching, the silicon substrate is directionally etched to form the space corresponding to the micro-electro-mechanical structure, and the space reaches the CMOS wafer.

14. The method of manufacturing a semiconductor microstructure as claimed in claim 7, wherein the CMOS wafer is directionally etched top the sacrificial layer by ion etching, and the sacrificial layer is isotropic etched.

15. The method of manufacturing a semiconductor microstructure as claimed in claim 9, wherein a plurality of holes is formed in the top surface of the CMOS wafer and located correspondingly to the micro-electro-mechanical structure, the sacrificial layer on the CMOS wafer doesn't cover the holes, a conductor resist layer is formed on the sacrificial layer in such a manner that an outer edge of the conductor resist layer is in contact with the storing layer, the conductor resist layer enters the holes of the CMOS wafer and is electrically connected to the micro-electro-mechanical structure, the conductor resist layer can allow electric connection to at least two micro-electro-mechanical structures after the sacrificial layer is etched out.

16. The method of manufacturing a semiconductor microstructure as claimed in claim 15, wherein the conductor resist layer is made of one of the materials: aluminum, nickel, silver, copper, and gold.

17. A method of manufacturing a semiconductor microstructure comprising: forming a standard CMOS wafer with at least one micro-electro-mechanical structure on one surface of a silicon substrate, grinding the silicon substrate thin, forming at least one resist layer on a surface of the CMOS wafer; etching the lower rear surface of the silicon base by deep reactive ion etching to form a space corresponding to the micro-electro-mechanical structure, and etching toward the resist layer, thus causing suspension of the micro-electro-mechanical structure.

18. The method of manufacturing a semiconductor microstructure as claimed in claim 17, wherein the CMOS wafer is etched to the resist layer by using ion etching, and the resist layer is etched by using anisotropic etching.
